(19) United States
(12) Patent Application Publication
(10) Pub. No.: US 2024/0039342 A1
(43) Pub. Date: Feb. 1, 2024

(54) WIRELESS CHARGING DEVICE WITH NFC FUNCTION

(71) Applicant: Hitachi-LG Data Storage Korea, Inc., Seoul (KR)

(72) Inventors: Sucheol KIM, Seoul (KR); Cheol JIN, Seoul (KR); Chaemin JU, Seoul (KR); Yurak SON, Seoul (KR); Hyeongyeon CHO, Seoul (KR); Suyoung LEE, Seoul (KR); Hyunuk HA, Seoul (KR); Hogil LEE, Seoul (KR)

(73) Assignee: Hitachi-LG Data Storage Korea, Inc., Seoul (KR)

(21) Appl. No.: 18/227,674

(22) Filed: Jul. 28, 2023

(30) Foreign Application Priority Data
Jul. 29, 2022 (KR) 10-2022-0094455

(51) Int. Cl. H02J 50/70; H02J 50/10; H02J 50/00; H05K 1/18; H05K 1/11

(52) U.S. Cl. CPC H02J 50/70; H02J 50/10; H02J 50/005; H05K 1/181; H05K 1/111; H05K 2201/1003

(57) ABSTRACT

The wireless charging device according to an embodiment may comprise a shielding assembly where a shield, a first coil for power transfer by magnetic inductive coupling, and a bracket are formed, an NFC coil fixed to the bracket, and a main PCB including an inverter that converts DC power into AC power and supplies it to the first coil. The bracket may be formed outside the first coil. The shielding assembly may further include a coil connector for connecting the first coil and the NFC coil to the main PCB. The coil connector may consist of a plurality of protruding pins, and the plurality of protruding pins may be inserted into holes formed at corresponding positions on the main PCB so that the first coil and the NFC coil are electrically connected to the main PCB.

### TECHNICAL FIELD

The present disclosure relates to a wireless charging device having an NFC function, and, more particularly, to a wireless charging device for a vehicle equipped with NFC antenna.

### BACKGROUND

Wireless charging refers to a technology in which power can be supplied from a device that sends power wirelessly to a device that receives power even when the two devices are not wired to each other. For example, the device receiving power may be a terminal such as a mobile phone, a smart phone, a PDA, or a tablet PC, and a battery provided inside the terminal may be charged by wireless charging.

In general, wireless charging technology is largely divided into a magnetic induction method, a magnetic resonance method, etc. The magnetic induction method is based on an electromagnetic induction phenomenon generated by the flow of electricity inside a device that sends power. For the magnetic resonance method to transfer power, when a certain resonance frequency is generated by the flow of electricity inside a device that sends power, a magnetic field is induced in a coil inside a device that receives power having a corresponding resonance frequency.

Recently, many car users are using a wireless charger mounted on the dashboard of a vehicle, and such a wireless charger can wirelessly charge a smart terminal such as a smart phone while serving as a cradle for using the screen or camera of the smart terminal as a navigation system or a dashcam.

A wireless charging device for a vehicle that has a near field communication (NFC) function to enhance drivers' convenience has been recently released, and the NFC function allows a smart device to access a vehicle system for starting up, configuring, etc. the vehicle. An NFC antenna for recognizing a digital key stored in a smart phone is embedded in such a wireless charging device for a vehicle.

However, as shown in FIG. 1, in the case of a conventional wireless charging device, to perform the NFC function, a printed circuit board (PCB) with a built-in NFC antenna is added, or an antenna pattern is added to a PCB for wireless charging. However, when the NFC function is carried out in such a manner, it inevitably results in an increase in the unit price of the product, and the NFC function cannot be fulfilled as expected by adding an antenna pattern to a PCB.

### SUMMARY

In view of such a situation, the purpose of the present disclosure is to propose a structure of an efficient NFC antenna for a wireless charging device for a vehicle.

The wireless charging device according to an embodiment of this disclosure may comprise a shielding assembly where a shield, a first coil for power transfer by magnetic inductive coupling, and a bracket are formed, an NFC coil fixed to the bracket, and a main PCB including an inverter that converts DC power into AC power and supplies it to the first coil.

Because it may be possible to perform an NFC function without a separate PCB, it may be possible to use the space where a PCB used to be placed, allowing for more freedom in design, and it may be possible to change the size, the number, etc. of windings of a coil easily so that it may be possible to respond to customer requests flexibly.

In addition, because there may be no need for a PCB to be added to a wireless charging device or for an antenna pattern to be added to the PCB in order to fulfill the NFC function, it may be possible to prevent the NFC function from not being fully performed and to obtain price competitiveness by cutting down the cost.

Furthermore, a separate PCB for performing the NFC function may not be added, and a space through which air can flow may be formed between a Tx coil and an upper case, so that it may be possible to resolve the problem of heat generation from a wireless charger.

### BRIEF DESCRIPTION OF THE DRAWINGS

FIG. 1 shows a conventional wireless charging device including a PCB which has an NFC antenna embedded and is separately from a charging module.

FIG. 2 is an exploded perspective view of a wireless charging device according to an embodiment of the present disclosure.

FIG. 3 is a detailed view of a shielding assembly around which an NFC antenna is wound.

FIG. 4 shows an example in which the NFC antenna is connected to a coil connector of the shielding assembly by soldering,

FIG. 5 is a side view and a top plan view of the wireless charging device with the NFC antenna wound around it.

FIGS. 6A and 6B respectively show the shielding assembly to which the NFC antenna is applied and the shielding assembly to which the NFC antenna is not applied.

FIG. 7 shows a process of coupling the NFC antenna with a bracket of the shielding assembly including a first coil.

FIG. 8 shows data resulting from the sensing of several NFC cards by the wireless charging device having the NFC antenna wound therein.

### DETAILED DESCRIPTION

Hereinafter, embodiments of a wireless charging device having an NFC function will be described in detail based on the accompanying drawings.

Regardless of the reference numerals, the same or similar components are given the same reference numerals, and overlapping descriptions thereof will be omitted.

In describing the embodiments disclosed in this specification, when an element is referred to as being “connected” to another element, it may be directly connected to the other element, but it should be understood that other components may exist in the middle.

In addition, in describing the embodiments disclosed in this specification, if it is determined that a detailed description of a related known technology may obscure the gist of the embodiment disclosed in this specification, the detailed description will be omitted. In addition, the accompanying drawings are only for easy understanding of the embodiments disclosed in this specification, and the technical idea disclosed in this specification is not limited by the accompanying drawings. And it should be understood that all changes, equivalents or substitutes included in the spirit and technical scope of this specification is included. In addition, the numbers (eg, first, second, etc.) used in the description process of this specification are only identification symbols for distinguishing one component from another component.

“Module” and “unit”, which are suffixes for components used in the following description, are given or used together in consideration of ease of writing the specification, and do not have meanings or roles that are distinct from each other by themselves.

In addition, the term disclosure can be replaced with terms such as document, specification, and description.

For contact power delivery or wireless charging, while a receiving module including a matching circuit consisting of a receiving (Rx) coil (or a second coil) and a capacitor and a rectifying circuit is close to a transmitting module including a resonant circuit consisting of a transmitting (Tx) coil (or a first coil) and a capacitor, an inverter, etc., a high-frequency alternating current may be made flow through the first coil to generate magnetic coupling between the first coil and the second coil, thereby delivering power to the receiving module.

A switching element of the inverter that converts DC power into AC power and supplies high-frequency AC power to the first coil operates at a high frequency, generating a lot of heat in the inverter and the transmitting coil.

In general, in a wireless charger, the distance between a transmitting (Tx) coil of a transmitting module and a receiving (Rx) coil of a receiving module is approximately 3 to 7 mm, and, considering the thickness of an interface case where a terminal to be charged is placed, etc., the distance from the upper surface of the transmitting coil to the upper surface of the case is approximately 2 to 5 mm.

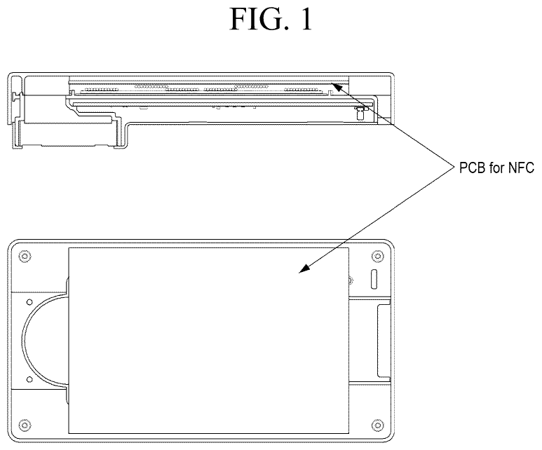

However, as shown in FIG. 1, when a PCB for NFC is placed on the transmitting coil, that is, between the transmitting coil and the case so that a wireless charging device has an NFC function, because there is no free space between the transmitting coil and the case, it is difficult to naturally cool the heat generated from the transmitting coil and the inverter, which limits the types of possible cooling methods.

Because the change in a magnetic field generated in a transmitting coil through which a high-frequency alternating current flows affects elements such as an inverter, a power supply device, a processor, and a memory of which a transmitting module consists, a transmitting coil of a wireless charging device is separated from other electronic elements by a shielding sheet.

For convenience of assembly, a shielding assembly including a transmitting coil and a shielding sheet and a circuit board (PCB) on which an inverter, a power supply device, a processor, a memory, etc. are mounted are assembled in a module form. The shielding assembly is disposed under an interface cover on which a smart terminal including a receiving module is placed, with the transmitting coil facing upward, and the PCB is disposed below the shielding assembly.

In the case of the conventional wireless charging device having an NFC function in FIG. 1, because a PCB having an NFC antenna embedded therein is disposed between a shielding assembly and an interface cover, as mentioned above, problems related to cooling may occur.

In the case of a wireless charging device according to an embodiment of the present disclosure, a bracket may be provided on the outside of a transmitting coil in a shielding assembly including the transmission coil, and a coil for an NFC antenna may be wound around the bracket, so that it may be possible to carry out an NFC function without employing a separate PCB with a built-in NFC antenna.

In addition, because it may be possible to change the shape of the bracket freely, it may be possible to adjust the coil for the NFC antenna depending on the size or shape of the shielding assembly, thereby maximizing the performance of the NFC antenna.

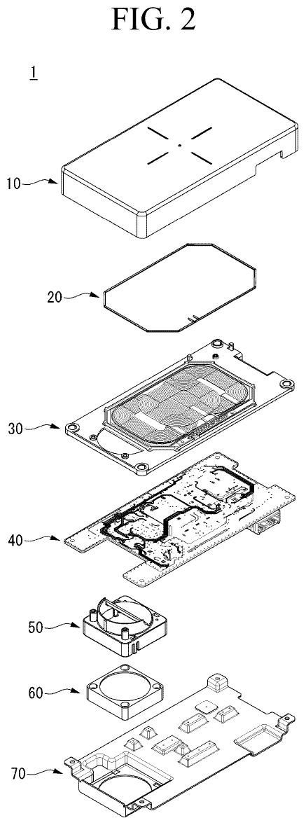

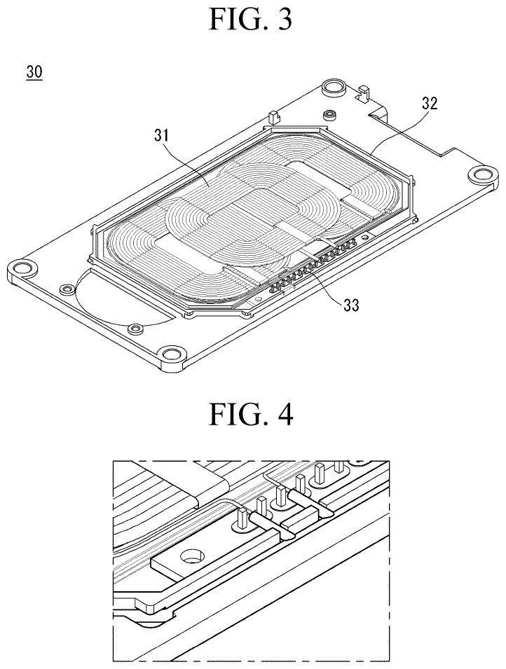

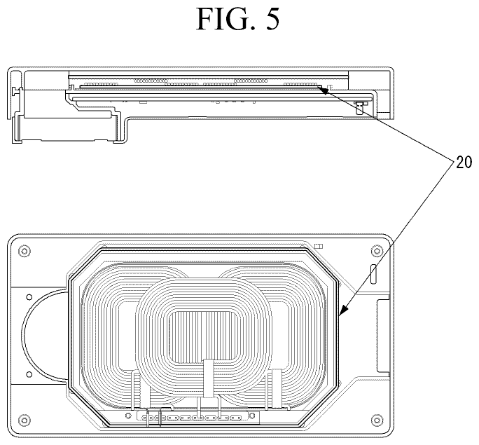

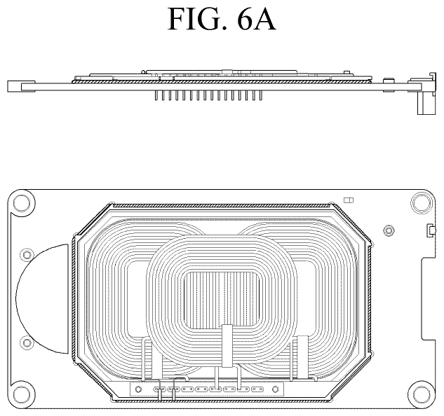

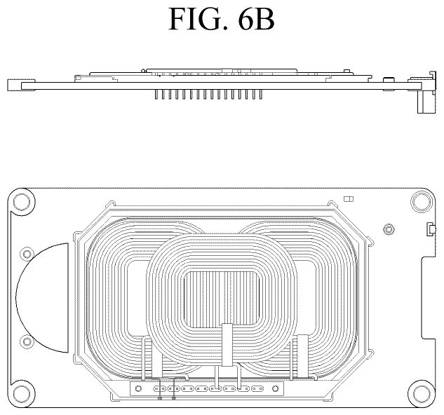

FIG. 2 is an exploded perspective view of the wireless charging device according to an embodiment of the present disclosure, FIG. 3 is a detailed view of a shielding assembly around which an NFC antenna is wound, FIG. 4 shows an example in which the NFC antenna is connected to a coil connector of the shielding assembly by soldering, FIG. 5 is a side view and a top plan view of the wireless charging device with the NFC antenna wound around it, and FIGS. 6A and 6B respectively show the shielding assembly to which the NFC antenna is applied and the shielding assembly to which the NFC antenna is not applied.

The wireless charging device 1 having an NFC function according to an embodiment of the present disclosure may include an upper case 10 forming an upper surface on which a smart terminal including a receiving module is placed, an NFC coil 20 serving as an NFC antenna for exchanging signals with a card with the NFC function, a shielding assembly 30 in which a transmitting coil is seated on a shield (e.g., a ferrite sheet) (not shown) for blocking electromagnetic waves of the transmitting coil, a power delivery module including an inverter, an NFC module for processing an NFC signal through the NFC antenna, a main PCB 40 in which a processor, etc. is embedded, a fan holder 50, a fan motor 60 for generating air flow for cooling, and a lower case 70 that protects internal components and forms the exterior of the device together with the upper case 10.

A mark indicating a position where a smart terminal to be charged is placed may be displayed on the upper surface of the upper case 10.

The NFC coil 20 may serve as the NFC antenna by being wound around a bracket provided on the shielding assembly 30. The NFC coil 20 serving as the NFC antenna may be disposed above a shielding sheet of the shielding assembly 30 so that performing an NFC function may not hinder performing wireless charging.

As shown in FIG. 3, the shielding assembly 30 may include a transmitting coil 31 (Tx coil) for wireless charging, a bracket 32 around which the NFC coil 20 is wound, and a coil connector 33 for connecting the NFC coil 20 and the transmitting coil 31 to the main PCB 40.

The transmitting coil 31 may consist of two or more coils in order to widen an active area corresponding to a position where power is transmitted to a receiving module, and may have a pattern of coils in the form of multi-layered spiral paths by the method of manufacturing a PCB. The transmitting coil 31 in FIGS. 2 and 3 consists of three coils.

The bracket 32 may be formed to protrude toward the upper case 10 on the outside of the transmitting coil 31, and may have a shape of a guide rib and a hook to fix the NFC coil 20.

It may be possible to change the planar shape of the bracket 32 freely based on the size or shape of the shielding assembly 30 in order to maximize the performance of the NFC antenna. In addition, it may be possible to adjust the planar shape or height of the bracket 32 based on air flow.

As shown in FIGS. 4, 6A, and 6B, the coil connector 33 may be formed with a plurality of pins protruding upward and downward, and the coil may be easily electrically connected to the pin by forming a pad with a pair of pins and fixing the end of the coil to the pad by soldering.

The coil connector 33 may consist of at least eight pins to connect the two ends of the NFC coil 20 and the two ends of the transmitting coil 31, and, when the transmitting coil 31 consists of multiple coils, the number of pins may be greater.

As shown in FIGS. 6A and 6B, a pin protruding downward of the coil connector 33 may be inserted into a hole on the main PCB 40 in order to electrically connect the NFC coil 20 and the transmitting coil 31 to the main PCB 40, and the pin inserted into the hole on the main PCB 40 may be soldered to a pad around the hole for secure electrical connection.

Holes or grooves may be formed on the shielding assembly 30 to form a path through which air flows by pressure generated by the fan motor 60, and the holes or grooves may be formed on opposite sides so that the air passing path may cross the transmitting coil 31.

As shown in FIGS. 5 and 6A, the wireless charging device 1 having an NFC function may be shipped with the NFC coil 20 wound around the bracket 32 of the shielding assembly 30, and, as shown in FIG. 6B, the wireless charging device 1 not having the NFC function may be shipped without the NFC coil 20.

As such, by modularizing the components of the wireless charging device 1, it may be possible to respond easily based on whether the device has the NFC function or not, reducing the manufacturing costs, and it may be possible to respond easily to customer requests, shortening the period for developing the device.

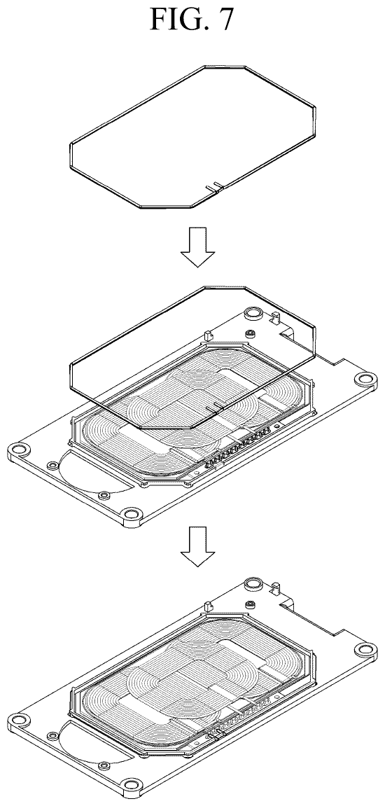

FIG. 7 shows a process of coupling the NFC antenna with the bracket of the shielding assembly including the first coil.

As shown in FIG. 7, instead of directly winding the NFC coil 20 around the bracket 32 of the shielding assembly 30, the NFC antenna already having a shape formed by winding the NFC coil 20 in the planar shape of the bracket 32 of the shielding assembly 30 may be inserted into the bracket 32.

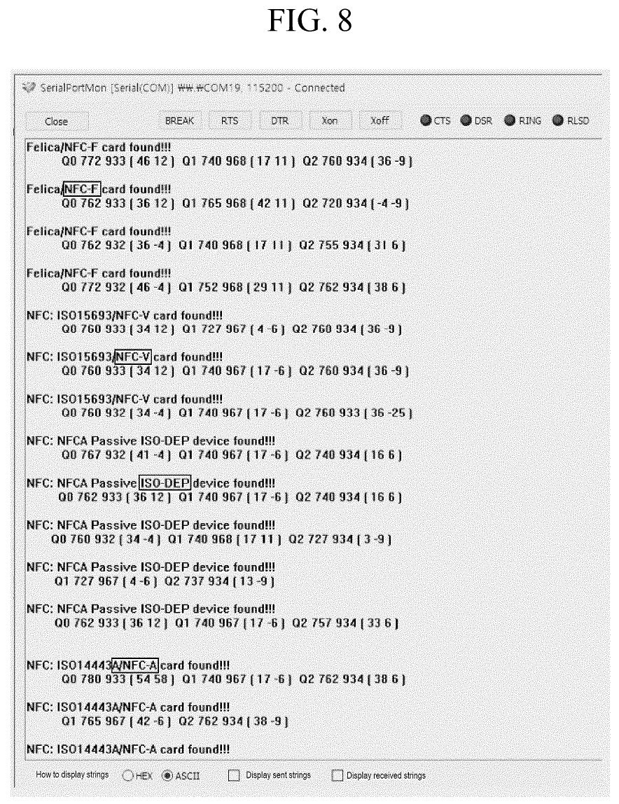

FIG. 8 shows data resulting from the sensing of several NFC cards by the wireless charging device having the NFC antenna wound therein.

An NFC antenna of similar size was made with an NFC coil to be used for the product in order to test whether it recognized cards for different types of NFC (e.g., NFC-A, NFC-F, NFC-V, ISO-DEP, etc.), and, as shown in FIG. 8, there was no problem in recognizing the NFCs.

Therefore, it may be possible to use the space where a PCB used to be placed, allowing more freedom in design, and it may be possible to change the size, the number, etc. of windings of the NFC coil easily so that it may be possible to respond to customer requests flexibly.

In addition, it was confirmed that the NFC function was fully fulfilled, and it may be possible to obtain price competitiveness by reducing the cost.

Furthermore, a space where air can flow may be formed between the transmitting coil and the upper case so that it may be possible to solve the problem of heat generation in the wireless charger.

The wireless charging device according to the present disclosure can be described as follows.

The wireless charging device according to an embodiment of the present disclosure may include the shielding assembly where the shield, the first coil for power transfer by magnetic inductive coupling, and the bracket are formed, the NFC coil fixed to the bracket, and the main PCB including the inverter that converts DC power into AC power and supplies it to the first coil.

According to an embodiment of the present disclosure, the bracket may be formed outside the first coil.

According to an embodiment of the present disclosure, the shielding assembly may further include the coil connector for connecting the first coil and the NFC coil to the main PCB.

According to an embodiment of the present disclosure, the coil connector may consist of the plurality of protruding pins, and the plurality of protruding pins may be inserted into holes formed at corresponding positions on the main PCB so that the first coil and the NFC coil may be electrically connected to the main PCB.

According to an embodiment of the present disclosure, the coil connector may further include a plurality of pads each of which is connected to two adjacent protruding pins, and the ends of the first coil or the NFC coil may be fixed to one of the plurality of pads by soldering.

According to an embodiment of the present disclosure, the wireless charging device may further include the fan motor for generating air flow. The holes or grooves may be formed on the opposite sides of the shielding assembly so that an air passing path by pressure generated by the fan motor is formed across the first coil.

Throughout the description, it should be understood by those skilled in the art that various changes and modifications are possible without departing from the technical principles of the present invention. Therefore, the technical scope of the present invention is not limited to the detailed descriptions in this specification but should be defined by the scope of the appended claims.

What is claimed is:

1. A wireless charging device comprising:
a shielding assembly where a shield, a first coil for power transfer by magnetic inductive coupling, and a bracket are formed,
an NFC coil fixed to the bracket, and
a main PCB including an inverter that converts DC power into AC power and supplies it to the first coil.

2. The wireless charging device of claim 1, wherein the bracket is formed outside the first coil.

3. The wireless charging device of claim 1, wherein the shielding assembly further includes a coil connector for connecting the first coil and the NFC coil to the main PCB.

4. The wireless charging device of claim 3, wherein the coil connector consists of a plurality of protruding pins, and the plurality of protruding pins are inserted into holes formed at corresponding positions on the main PCB so that the first coil and the NFC coil are electrically connected to the main PCB.

5. The wireless charging device of claim 4, wherein the coil connector further includes a plurality of pads each of which is connected to two adjacent protruding pins, and the ends of the first coil or the NFC coil are fixed to one of the plurality of pads by soldering.

6. The wireless charging device of claim 1, further comprising a fan motor for generating air flow, wherein holes or grooves are formed on the opposite sides of the shielding assembly so that an air passing path by pressure generated by the fan motor is formed across the first coil.
